(19) United States
(12) Patent Application Publication
(10) Pub. No.: US 2024/0274683 A1
(43) Pub. Date: Aug. 15, 2024

(54) METHOD FOR PREPARING SHIELDED GATE SEMICONDUCTOR DEVICE STRUCTURE, AND SHIELDED GATE SEMICONDUCTOR DEVICE STRUCTURE

(71) Applicant: WILL SEMICONDUCTOR (SHANGHAI) CO. LTD., Shanghai (CN)

(72) Inventors: Shuangshen LE, Shanghai (CN); Zengyi HE, Shanghai (CN); Libo ZHANG, Shanghai (CN); Xingmin WU, Shanghai (CN); Qingwen YUAN, Shanghai (CN)

(73) Assignee: WILL SEMICONDUCTOR (SHANGHAI) CO. LTD., Shanghai (CN)

(21) Appl. No.: 18/570,253

(22) PCT Filed: Dec. 15, 2021
(86) PCT No.: PCT/CN2021/138151

§ 371 Date: Dec. 14, 2023

(30) Foreign Application Priority Data
Dec. 13, 2021 (CN) 202111518986.8

(51) Int. Cl. H01L 29/423; H01L 21/28; H01L 29/40

(52) U.S. Cl. CPC H01L 29/4236; H01L 21/28035; H01L 29/401

(57) ABSTRACT

A method for preparing a shielded gate semiconductor device structure, and a shielded gate semiconductor device structure. The following steps are added in between source polycrystalline silicon deposition and gate polycrystalline silicon oxidation: removing, by etching, a first oxide layer and a second oxide layer that are in a middle upper space of a cell trench and on the surface of a semiconductor material layer, and a portion of the semiconductor material layer between trenches; removing, by etching, the gate polycrystalline silicon until a thickness of remaining gate polycrystalline silicon in the source lead-out region trench reaches a preset thickness; and selectively removing, by etching, remaining gate polycrystalline silicon in the source lead-out region trench until no gate polycrystalline silicon remains in the source lead-out region trench, and then removing the photoresist.

### TECHNICAL FIELD

Embodiments of this application pertain to the technical field of integrated circuit art, and in particular, relate to a method for preparing a shielded gate semiconductor device structure, and a shielded gate semiconductor device structure.

### BACKGROUND

The on-resistance and parasitic capacitance of power MOSFETs are conflicting parameters. To reduce the on-resistance, it is necessary to increase the silicon wafer area. An increase in silicon wafer area in turn leads to an increase in the parasitic capacitance. Therefore, for a given silicon wafer area, the parasitic capacitance can be reduced only by using new process technologies. The shielding technology of shielded gate semiconductor device (Shield Gate Trench MOSFET) effectively solves the contradiction between the on-resistance and the parasitic capacitance.

Except for the gate structure, the other parts are the same as a standard power MOSFET that uses the trench art. The gate is divided into upper and lower parts, with the lower part shielded by some special materials. The lower part is internally connected to the upper part of the gate, while the shielding layer of the lower part of the gate is connected to the source, thereby reducing the parasitic Miller capacitance between the drain and the gate of the MOSFET. This greatly reduces the duration of the Miller plateau during switching and decreases the switching loss. Moreover, this structure changes the shape of the internal electric field by transforming the traditional triangular electric field into a more compressed trapezoidal electric field. As a result, the thickness of the epitaxial layer is further reduced and the on-resistance and the thermal resistance are decreased.

However, due to the special nature of shielded gate semiconductor devices, the trenches must be deeply etched, and the thickness of the oxide layer at the bottom of the trenches is also relatively thick. The higher the device voltage, the deeper the trenches are and the thicker the oxide layer at the bottom of the trenches becomes. This can lead to a situation where the number of oxygen atoms reaching the bottom of the trenches during the growth of the thermal oxide layer in the deep trenches is less than the number of oxygen atoms reaching the surface. As a result, the nearer to the bottom of the trenches, the thinner the oxide layer is. Furthermore, due to differences in crystal orientations at the bottom of the trenches, the oxide layer at bottom corners is even thinner. This results in a significant difference in the thickness of the oxide layer at the top of the semiconductor material between the trenches and the thickness of the oxide layer at the corners of the trenches, leading to significant challenges to product design and subsequent processing.

To address the above technical problem, as shown in FIG. 1, the prior art uses a method of growing a first oxide layer by thermal oxidation at the bottom of the trenches, followed by depositing a second oxide layer. However, when the thickness of the thick oxide layer exceeds the preset thickness, as the proportion of the second oxide layer in the total oxide layer thickness is getting higher, the oxide layer in the source polycrystalline silicon lead-out region is also etched during the etching of the thick oxide layer. Additionally, pits are produced on the sidewalls of trenches in the source lead-out region. During the deposition of the gate polycrystalline silicon, the gate polycrystalline silicon will enter the pits, and subsequent processes are unable to completely remove the gate polycrystalline silicon from the pits, causing a higher risk of gate-source short circuits and an uncontrollable risk in the yield.

### SUMMARY

To partially solve or alleviate the technical problems in the prior art, embodiments of this application provide a method for preparing a shielded gate semiconductor device structure, and a shielded gate semiconductor device structure.

The technical solution used by the embodiments of this application to partially solve or alleviate the technical problems in the prior art is: the embodiments of this application provide a method for preparing a shielded gate semiconductor device, and the method includes:

forming a second oxide layer and a first oxide layer sequentially from outside to inside on inner surfaces of both a cell trench and a source lead-out region trench:

depositing source polycrystalline silicon in spaces enclosed by the second oxide layers in both the cell trench and the source lead-out region trench:

removing by etching source polycrystalline silicon on the surface of a semiconductor material layer and selectively removing by etching a portion of the source polycrystalline silicon in an upper space of the cell trench:
removing by etching the first oxide layer and the second oxide layer that are on the surface of the semiconductor material layer, in the cell trench, and in the source lead-out region trench:

removing by etching the semiconductor material layer between the trenches and a portion of the source polycrystalline silicon in the cell trench and the source lead-out region trench:

forming a third oxide layer on an upper surface of the semiconductor material layer, an exposed surface of the cell trench, an exposed surface of the source lead-out region trench, and an exposed surface of the source polycrystalline silicon, and then removing the third oxide layer:

forming a fourth oxide layer on the upper surface of the semiconductor material layer, the exposed surface of the cell trench, the exposed surface of the source lead-out region trench, and the exposed surface of the source polycrystalline silicon;

depositing gate polycrystalline silicon in the cell trench and the source lead-out region trench; and

removing by etching the gate polycrystalline silicon on the surface of the semiconductor material layer and selectively removing by etching the gate polycrystalline silicon in the source lead-out region trench until no gate polycrystalline silicon remains in the source lead-out region trench.

According to a preferred embodiment of this application, the first oxide layer is formed by thermal growth, and the second oxide layer is formed by chemical vapor deposition.

According to a preferred embodiment of this application, total thickness of the first oxide layer and the second oxide layer is between 1,000 A and 8,000 A and a ratio of the thickness of the first oxide layer to thickness of the second oxide layer is between 0.2 and 1.8.

According to a preferred embodiment of this application, an etching speed for the first oxide layer is smaller than an etching speed for the second oxide layer.

According to a preferred embodiment of this application, after the removing by etching the first oxide layer and the second oxide layer that are on the surface of the semiconductor material layer and in the cell trench and the source lead-out region trench by etching, respectively, a height difference between the top of the remaining source polycrystalline silicon in a cell trench and the bottom of a top surface of the second oxide layer in the same cell trench is between 5,000 A and 15,000 A, and a height difference between the top of the remaining source polycrystalline silicon in a source lead-out region trench and the bottom of a top surface of the second oxide layer in the same source lead-out region trench is between 3,000 A and 12,000 A.

According to a preferred embodiment of this application, after the removing by etching the semiconductor material layer between the trenches and a portion of the source polycrystalline silicon in the cell trench and the source lead-out region trench, a height difference between the top of the remaining source polycrystalline silicon and the bottom of a top surface of the second oxide layer in the cell trench is between 500 A and 1,500 A, and a height difference between the top of the remaining source polycrystalline silicon and the bottom of a top surface of the second oxide layer in the source lead-out region trench is between 0 A and 1,000 A.

According to a preferred embodiment of this application, thickness of the semiconductor material layer between the trenches that is removed by etching is between 3,000 A and 10,000 A.

According to a preferred embodiment of this application, a third oxide layer with a thickness of 200 A to 1,000 A is grown at a temperature of 950° C. to 1,100° C., and a fourth oxide layer with a thickness of 200 A to 1,200 A is grown at a temperature of 950° C. to 1,100° C.

Compared with the prior art, the embodiments of this application provide a method for preparing a shielded gate semiconductor device structure, by which the following steps are added in between of source polycrystalline silicon deposition and gate polycrystalline silicon oxidation: removing by etching the first oxide layer and the second oxide layer that are on the surface of the semiconductor material layer and in the cell trench and the source lead-out region trench: removing by etching the semiconductor material layer between the trenches and a portion of the source polycrystalline silicon in the cell trench and the source lead-out region trench: forming a third oxide layer on an upper surface of the semiconductor material layer, an exposed surface of the cell trench, an exposed surface of the source lead-out region trench, and an exposed surface of the source polycrystalline silicon, and then removing the third oxide layer: forming a fourth oxide layer on the upper surface of the semiconductor material layer, the exposed surface of the cell trench, the exposed surface of the source lead-out region trench, and the exposed surface of the source polycrystalline silicon: depositing gate polycrystalline silicon in the cell trench and the source lead-out region trench; and removing by etching the gate polycrystalline silicon on the surface of the semiconductor material layer and selectively removing by etching the gate polycrystalline silicon in the source lead-out region trench until no gate polycrystalline silicon remains in the source lead-out region trench. In embodiments of this application, gate polycrystalline silicon is removed by etching until gate polycrystalline silicon in the source lead-out region trench is completely removed by etching. Thus, the problem of residue of gate polycrystalline silicon at sidewalls of the source lead-out region trench is solved and the risk of gate-source short circuits is avoided. Yield and reliability are also improved.

According to a second aspect, the embodiments of this application further provide a shielded gate semiconductor device structure which is prepared and obtained by using the above preparing method, where the structure includes:
a cell trench, where an inner surface of a lower part of the cell trench is sequentially provided with a second oxide layer and a first oxide layer from outside to inside and an inner surface of an upper part of the cell trench is provided with a fourth oxide layer, where source polycrystalline silicon is provided in a space enclosed by the second oxide layer and gate polycrystalline silicon is provided in a space enclosed by the fourth oxide layer, a top surface of the source polycrystalline silicon being provided with a fourth oxide layer, and the gate polycrystalline silicon covering the top surface of the source polycrystalline silicon; and a source lead-out region trench, where an inner surface of the source lead-out region trench is provided with a first oxide layer and a second oxide layer, and source polycrystalline silicon is provided in a space enclosed by the second oxide layer, where a top surface of the source polycrystalline silicon is provided with a fourth oxide layer:

where in the cell trench and the source lead-out region trench, the top of the second oxide layer is lower than the top of the first oxide layer.

According to a preferred embodiment of this application, total thickness of the first oxide layer and the second oxide layer is between 1,000 A and 8,000 A.

According to a preferred embodiment of this application, thickness of the fourth oxide layer is between 200 A and 12,00 A.

Compared with the prior art, the shielded gate semiconductor device structure provided in the second aspect has the same beneficial effects as the method for preparing a shielded gate semiconductor device structure provided in the first aspect, and the beneficial effects will not be further described here.

### BRIEF DESCRIPTION OF DRAWINGS

The accompanying drawings described herein are intended for better understanding of this application, and constitute a part of this application. Exemplary embodiments and descriptions thereof in this application are intended to interpret this application and do not constitute any inappropriate limitation on this application. Specific embodiments of this application will be described in detail in the following with reference to the accompanying drawings in an exemplary rather than restrictive manner. In the accompanying drawings, same reference signs denote same or similar components or parts. Those skilled in the art should understand that these drawings may not necessarily be drawn to scale. In the drawings:

FIG. 1 is a schematic structural diagram of a shielded gate semiconductor device prepared through a preparation process in the prior art:

FIG. 2 is a flowchart of a method for preparing a shielded gate semiconductor device according to an embodiment of this application:

FIG. 3 is a schematic structural diagram corresponding to a process step according to embodiments of this application:

FIG. 4 is a schematic structural diagram corresponding to a process step according to embodiments of this application:

FIG. 5 is a schematic structural diagram corresponding to a process step according to embodiments of this application:

FIG. 6 is a schematic structural diagram corresponding to a process step according to embodiments of this application:

FIG. 7 is a schematic structural diagram corresponding to a process step according to embodiments of this application:

FIG. 8 is a schematic structural diagram corresponding to a process step according to embodiments of this application:

FIG. 9 is a schematic structural diagram corresponding to a process step according to embodiments of this application:

FIG. 10 is a schematic structural diagram corresponding to a process step according to embodiments of this application:

FIG. 11 is a schematic structural diagram corresponding to a process step according to embodiments of this application:

FIG. 12 is a schematic structural diagram corresponding to a process step according to embodiments of this application; and

FIG. 13 is a schematic structural diagram of a shielded gate semiconductor device structure contained in embodiments of this application.

### DETAILED DESCRIPTION OF EMBODIMENTS

To make persons of ordinary skill in the art understand this application better, the following clearly and completely describes the technical solutions in the embodiments of this application with reference to the accompanying drawings in the embodiments of this application. Apparently, the described embodiments are merely some but not all of the embodiments of this application. All other embodiments obtained by persons of ordinary skill in the art based on the embodiments of this application without creative efforts fall within the protection scope of this disclosure.

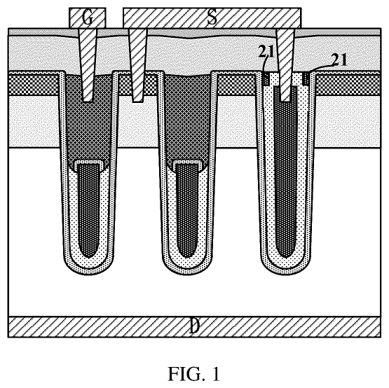

As shown in FIG. 1, FIG. 1 is a shielded gate semiconductor device structure prepared through a preparation process in the prior art. Steps of the specific method for preparing the shielded gate semiconductor device structure shown in FIG. 1 are as follows:

Step S01: Firstly, form multiple cell trenches and source lead-out region trenches on an epitaxial layer through photolithography-etching, and then form a second oxide layer and a first oxide layer sequentially from outside to inside on inner surfaces of the cell trenches and the source lead-out region trenches.

Step S02: Deposit source polycrystalline silicon in the cell trenches and the source lead-out region trenches, then perform etching on the source polycrystalline silicon on the surface of a semiconductor material layer once until no source polycrystalline silicon remains on the surface of the semiconductor material layer, and perform photolithography-etching on the source polycrystalline silicon in the cell region and remove the photoresist.

Step S03: Remove by etching the first oxide layer and the second oxide layer that are on the surface of the semiconductor material layer and in the cell trenches and the source lead-out region trenches.

Step S04: Form a third oxide layer on an upper surface of the semiconductor material layer, an exposed surface of the cell trenches, an exposed surface of the source lead-out region trenches, and an exposed surface of the source polycrystalline silicon, and then remove the third oxide layer.

Step S05: Form a fourth oxide layer on the upper surface of the semiconductor material layer, the exposed surface of the cell trenches, the exposed surface of the source lead-out region trenches, and the exposed surface of the source polycrystalline silicon.

Step S05: Deposit gate polycrystalline silicon in the cell trenches and the source lead-out region trenches.

Step S06: Perform etching on the gate polycrystalline silicon on the surface of the semiconductor material layer.

As can be seen from the above process, due to the presence of both the cell region and the source lead-out region in the shielded gate semiconductor device, when the total thickness of the first oxide layer and the second oxide layer exceeds 1,000 A and the proportion of the second oxide layer in the total oxide layer thickness is getting higher, the first oxide layer and the second oxide layer in the source lead-out region are also etched when etching is performed on the first oxide layer and the second oxide layer, because the etching speed for the second oxide layer is faster. As a result, pits 21 are produced on the sidewalls of trenches in the source lead-out region. During the deposition of the gate polycrystalline silicon, the gate polycrystalline silicon will enter the pits 21, and subsequent processes are unable to completely remove the gate polycrystalline silicon from the pits 21. Therefore, the risk of gate-source short circuits is getting higher, resulting in the problem of an uncontrollable risk in the yield and an unavoidable risk in the reliability of the shielded gate semiconductor device.

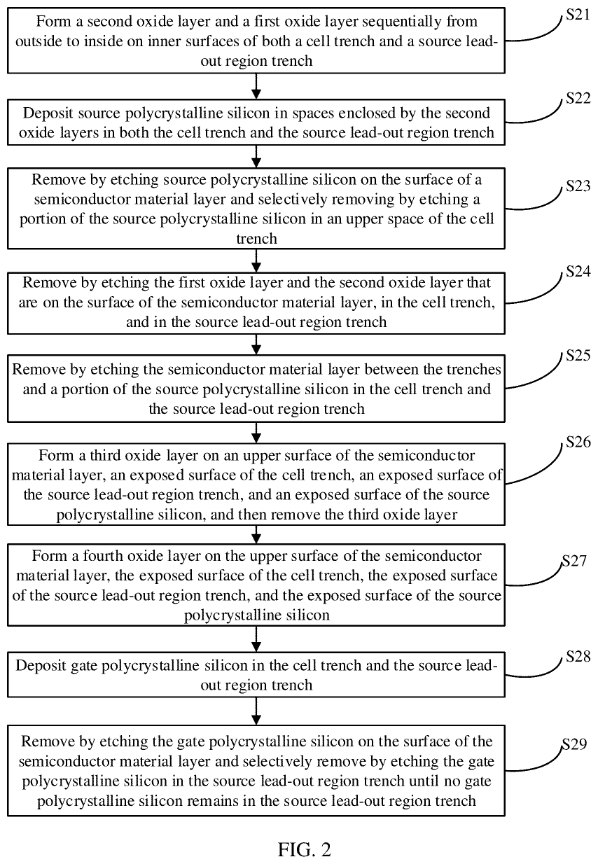

As shown in FIG. 2, FIG. 2 is a flowchart of a method for preparing a shielded gate semiconductor device structure according to an embodiment of this application. The method includes the following steps.

Step S21: Form a second oxide layer and a first oxide layer sequentially from outside to inside on inner surfaces of both a cell trench and a source lead-out region trench.

Step S22: Deposit source polycrystalline silicon in spaces enclosed by the second oxide layers in both the cell trench and the source lead-out region trench.

Step S23: Remove by etching source polycrystalline silicon on the surface of a semiconductor material layer and selectively removing by etching a portion of the source polycrystalline silicon in an upper space of the cell trench:

Step S24: Remove by etching the first oxide layer and the second oxide layer that are on the surface of the semiconductor material layer and in the cell trench and the source lead-out region trench.

Step S25: Remove by etching the semiconductor material layer between the trenches and a portion of the source polycrystalline silicon in the cell trench and the source lead-out region trench.

Step S26: Form a third oxide layer on an upper surface of the semiconductor material layer, an exposed surface of the cell trench, an exposed surface of the source lead-out region trench, and an exposed surface of the source polycrystalline silicon, and then remove the third oxide layer.

Step S27: Form a fourth oxide layer on the upper surface of the semiconductor material layer, the exposed surface of the cell trench, the exposed surface of the source lead-out region trench, and the exposed surface of the source polycrystalline silicon.

Step S28: Deposit gate polycrystalline silicon in the cell trench and the source lead-out region trench.

Step S29: Remove by etching the gate polycrystalline silicon on the surface of the semiconductor material layer and selectively remove by etching the gate polycrystalline silicon in the source lead-out region trench until no gate polycrystalline silicon remains in the source lead-out region trench.

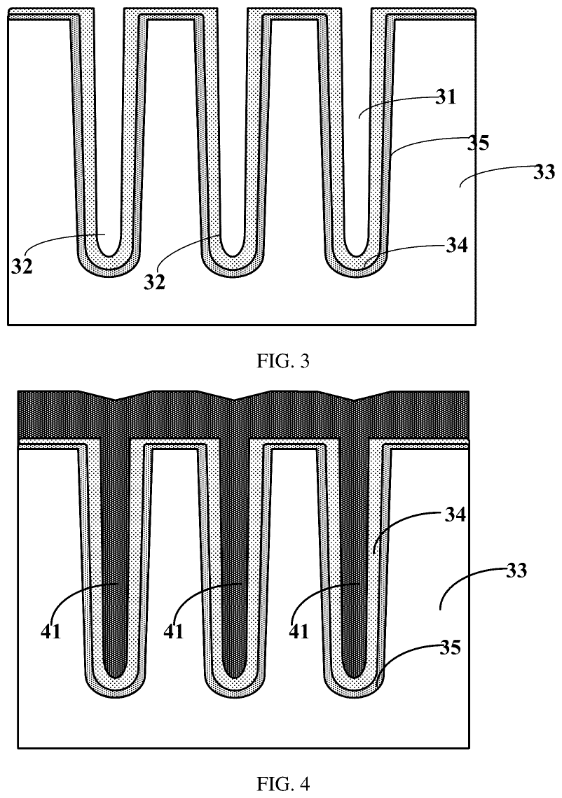

Refer to FIG. 2 and FIG. 3. The process for forming a cell trench 32 and source lead-out region trench 31 on a semiconductor layer 33 is well known to those skilled in the art and are not elaborated on here. The semiconductor material layer may be a substrate 33 or an epitaxial layer 33. After the cell trench 32 and source lead-out region trench 31 are formed by direct photolithography-etching on the semiconductor layer 33, a first oxide layer 35 is first generated on the inner surfaces of the cell trench 32 and the source lead-out region trench 31 by a thermal growth process, and then a second oxide layer 34 is generated on the outer surface of the first oxide layer 35 by a chemical vapor deposition process. The first oxide layer 35 and the second oxide layer 34 are referred to as thick oxide layers, and the total thickness of the first oxide layer 35 and the second oxide layer 34 is between 1,000 A and 8,000 A. The ratio of the thicknesses of the first oxide layer 35 to the second oxide layer 34 is between 0.2 and 1.8. Typically, the quantity of cell trenches 32 is greater than the quantity of source lead-out region trenches 31.

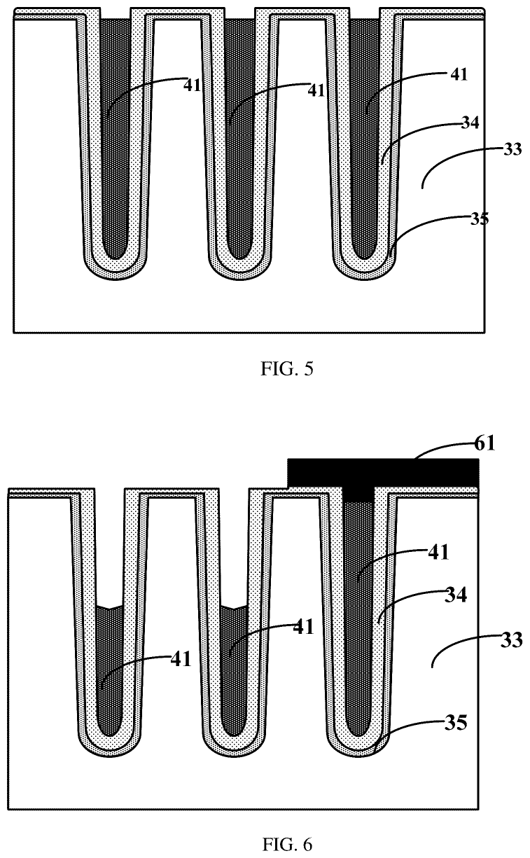

Refer to FIG. 2, FIG. 4, and FIG. 5. Source polycrystalline silicon 41 is deposited in spaces enclosed by the second oxide layers 34 in both the cell trenches 32 and the source lead-out region trenches 31, and then the source polycrystalline silicon 41 is etched back until the top of the source polycrystalline silicon 41 is not higher than the top of the trenches. That is, the source polycrystalline silicon 41 on the surface of the polycrystalline semiconductor layer 33 is etched back to ensure that there is no source polycrystalline silicon 41 on the surface of the semiconductor layer 33.

Refer to FIG. 2 and FIG. 6. Photoresist second 61 is applied on the source lead-out region and then a photolithography-etching process is performed on the source polycrystalline silicon 41 in the middle upper space of the cell trench 32, leaving some of the source polycrystalline silicon 41 in the cell trench 32. After that, the photoresist second 61 is removed.

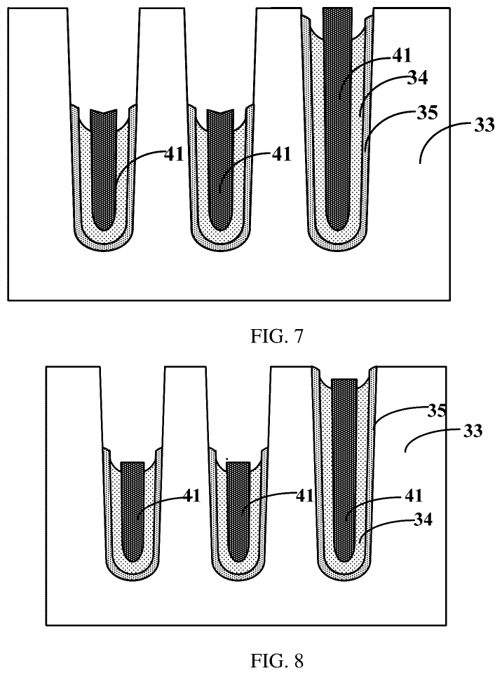

Refer to FIG. 2 and FIG. 7. The first oxide layer 35 and the second oxide layer 34 that are in the middle upper space of the cell trench 32 and the source lead-out region trench 31 and on the surface of the semiconductor layer 33 are removed by etching. Because the etching speed for the first oxide layer 35 is lower than the etching speed for the second oxide layer 34, the top of the first oxide layer is higher than the top of the second oxide layer 34 after etching. After the first oxide layer 35 and the second oxide layer 34 in the cell trench 32 are removed by etching, the height difference between the top of the remaining source polycrystalline silicon 41 in a cell trench 32 and the bottom of a top surface of the second oxide layer 34 in the same cell trench 32 is between 5,000 A and 15,000 A. The height difference between the top of the remaining source polycrystalline silicon 41 in a source lead-out region trench 31 and the bottom of a top surface of the second oxide layer 34 in the same source lead-out region trench 31 is between 3,000 A and 12,000 A.

Refer to FIG. 1 and FIG. 8. After the semiconductor layer 33 between the trenches and a portion of the source polycrystalline silicon in the cell trench 32 and the source lead-out region trench 31 are removed by etching, a height difference between the top of the source polycrystalline silicon 41 and the bottom of a top surface of the second oxide layer 34 in the cell trench 32 is between 500 A and 1,500 A: a height difference between the top of the source polycrystalline silicon trenches and the bottom of a top surface of the second oxide layer in the source lead-out region trench is between 0 A and 1,000 A; and the etchback thickness of the semiconductor layer 33 between the trenches is between 3,000 A and 10,000 A. The specific etchback thickness of the semiconductor layer 33 between the trenches depends on the height difference between the bottom of the second oxide layer 34 in the source lead-out region trench 31 and the semiconductor layer 33 between the trenches.

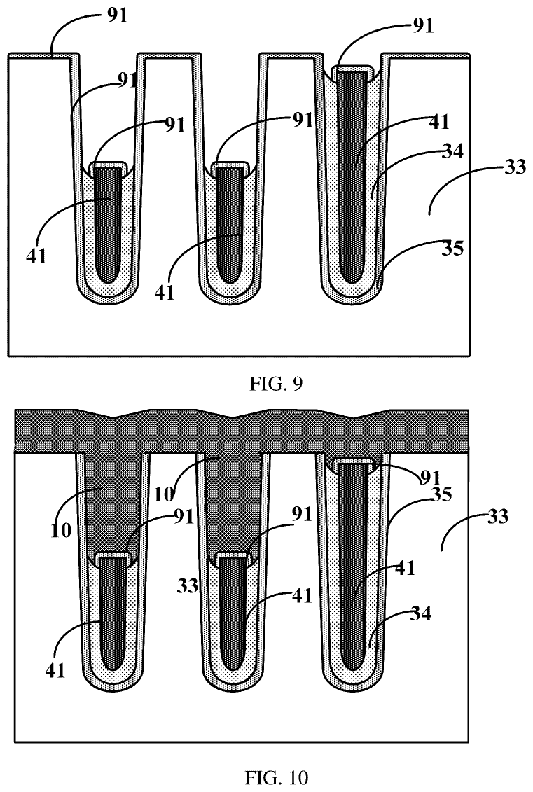

Refer to FIG. 2 and FIG. 9. On the basis of FIG. 8, a third oxide layer (not shown) is formed on the surface of the semiconductor layer 33, the upper surface of the semiconductor layer 33, the exposed surface of the cell trench 32, the exposed surface of the source lead-out region trench 31, and the exposed surface of the source polycrystalline silicon 41, and then the third oxide layer (not shown) is removed. The third oxide layer (not shown) can be used to process the morphology and improve the purity of the surfaces in contact with the third oxide layer. The thickness of the third oxide layer is between 200 A and 1,000 A, and the process temperature is between 950° C. and 1,100° C.

After the removal of the third oxide layer (not shown), a fourth oxide layer 91 is formed at the location where the third oxide layer (not shown) was located, that is, on the surface of the semiconductor layer 33, the inner surface of the cell trench 32, the inner surface of the source lead-out region trench 31, and the top of the source polycrystalline silicon 41. The thickness of the fourth oxide layer 91 is between 200 A and 1,200 A and the process temperature is between 950 C and 1,100° C.

Refer to FIG. 2 and FIG. 10. Gate polycrystalline silicon 10 is deposited in the upper space of the cell trench 32. The process of depositing gate polycrystalline silicon 10 is a well-known technique in the art and is not elaborated herein.

As shown in FIG. 2 and FIG. 11, the gate polycrystalline silicon 10 is etched back until no gate polycrystalline silicon 10 remains on the surface of the semiconductor layer 33. The thickness of the remaining gate polycrystalline silicon 93 in the source lead-out region trench 31 is between 0 A and 5,000 A.

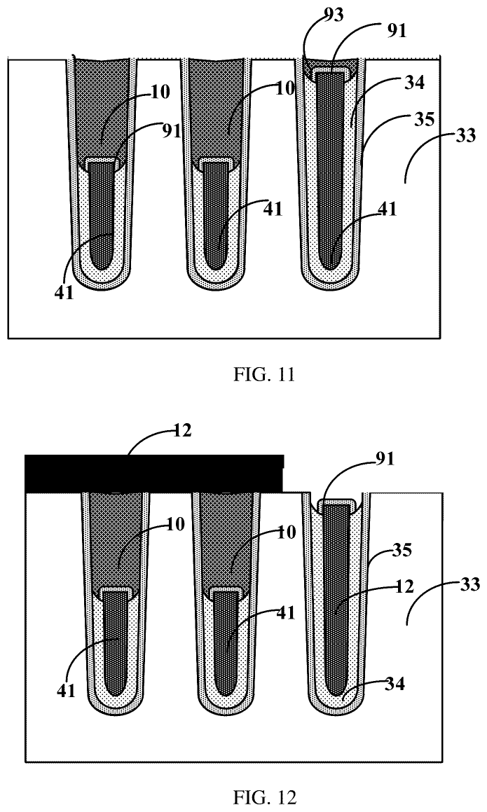

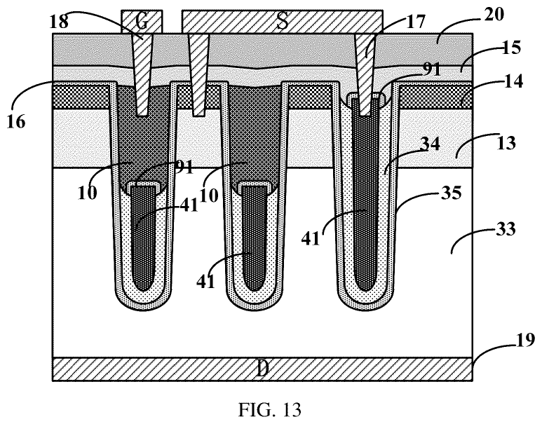

Refer to FIG. 2 and FIG. 12. On the basis of FIG. 11, photoresist first 12 is applied and photolithography-etching is performed on the remaining gate polycrystalline silicon 93 in the upper space of the source lead-out region trench 31 until the remaining gate polycrystalline silicon 93 in the source lead-out region trench 31 is completely removed by etching. Then, the photoresist first 12 is removed. At this time, no gate polycrystalline silicon 93 remains in the source lead-out region trenches 31. In the embodiments of this application, gate polycrystalline silicon is removed by etching until gate polycrystalline silicon in the source lead-out region trench is completely removed by etching. Thus, the problem of residue of gate polycrystalline silicon at sidewalls of the source lead-out region trench is solved and the risk of gate-source short circuits is avoided. Yield and reliability are also improved.

The shielded gate semiconductor device structure prepared by the above process steps in the embodiments of this application is shown in FIG. 12. The shielded gate semiconductor device structure includes:
a cell trench 32, where an inner surface of a lower part of the cell trench 32 is sequentially provided with a second oxide layer 34 and a first oxide layer 35 from outside to inside and an inner surface of an upper part of the cell trench 32 is provided with a fourth oxide layer 91, where source polycrystalline silicon 41 is provided in a space enclosed by the second oxide layer 34 and gate polycrystalline silicon 10 is provided in a space enclosed by the fourth oxide layer 91, a top surface of the source polycrystalline silicon 41 being provided with a fourth oxide layer 91, and the gate polycrystalline silicon 10 covering the top surface of the source polycrystalline silicon 41; and a source lead-out region trench 31, where an inner surface of the source lead-out region trench 31 is provided with a first oxide layer 35 and a second oxide layer 34, and source polycrystalline silicon 41 is provided in a space enclosed by the second oxide layer 34, where a top surface of the source polycrystalline silicon 41 is provided with a fourth oxide layer 91:

where in the cell trench 32 and the source lead-out region trench 31, the top of the second oxide layer 34 is lower than the top of the first oxide layer 35, the total thickness of the first oxide layer 35 and the second oxide layer 34 is between 1,000 A and 8,000 A, and the thickness of the fourth oxide layer 91 is between 200 A and 1,200 A.

Subsequently, an oxide layer 16 is formed on the surface of the entire semiconductor layer 33, and ion implantation and drive-in is then carried out sequentially to form a well 13. Afterwards, photolithography-etching is performed on the well 13 to form an implantation region 14 in the well 13. Then, dielectric layers 15 and 20 are formed by deposition, and contact holes 17 and 18 are formed by photolithography-etching. Next, ions are implanted into contact holes 17 and 18 and activated and multiple layers of metal are deposited in the contact holes 17 and 18 to form lead-out electrodes. Finally, a device with the shielded gate semiconductor device structure is formed.

In the embodiments of this application, by providing the shielded gate semiconductor device structure, the problem of residue of gate polycrystalline silicon at sidewalls of the source lead-out region trench is solved and the risk of gate-source short circuits is avoided. Yield and reliability are also improved.

In conclusion, it should be noted that the above embodiments are merely intended for describing the technical solutions of this application but not for limiting this application. Although this application is described in detail with reference to the foregoing embodiments, persons of ordinary skill in the art should understand that they may still make modifications to the technical solutions described in the foregoing embodiments or make equivalent replacements to some or all technical features thereof without departing from the scope of the technical solutions of the embodiments of this application.

1-10. (canceled)

11. A method for preparing a shielded gate semiconductor device, the method comprising:
forming a second oxide layer and a first oxide layer sequentially, from outside to inside, on inner surfaces of both a cell trench and a source lead-out region trench;
depositing source polycrystalline silicon in spaces enclosed by the second oxide layers in both the cell trench and the source lead-out region trench;
removing, by etching, source polycrystalline silicon on the surface of a semiconductor material layer and selectively removing, by etching, a portion of the source polycrystalline silicon in an upper space of the cell trench;
removing, by etching, the first oxide layer and the second oxide layer that are on the surface of the semiconductor material layer, in the cell trench, and in the source lead-out region trench;
removing, by etching, the semiconductor material layer between the trenches and a portion of the source polycrystalline silicon in the cell trench and the source lead-out region trench;
forming a third oxide layer on an upper surface of the semiconductor material layer, an exposed surface of the cell trench, an exposed surface of the source lead-out region trench, and an exposed surface of the source polycrystalline silicon, and then removing the third oxide layer;
forming a fourth oxide layer on the upper surface of the semiconductor material layer, the exposed surface of the cell trench, the exposed surface of the source lead-out region trench, and the exposed surface of the source polycrystalline silicon;
depositing gate polycrystalline silicon in the cell trench and the source lead-out region trench; and
removing, by etching, the gate polycrystalline silicon on the surface of the semiconductor material layer and selectively removing by etching the gate polycrystalline silicon in the source lead-out region trench until no gate polycrystalline silicon remains in the source lead-out region trench.

12. The method for preparing a shielded gate semiconductor device according to claim 11, wherein the first oxide layer is formed by thermal growth, and the second oxide layer is formed by chemical vapor deposition.

13. The method for preparing a shielded gate semiconductor device according to claim 11, wherein total thickness of the first oxide layer and the second oxide layer is between 1,000 A and 8,000 A and a ratio of thickness of the first oxide layer to thickness of the second oxide layer is between 0.2 and 1.8.

14. The method for preparing a shielded gate semiconductor device structure according to claim 11, wherein an etching speed for the first oxide layer is smaller than an etching speed for the second oxide layer.

15. The method for preparing a shielded gate semiconductor device according to claim 11, wherein after removing, by etching, the first oxide layer and the second oxide layer that are on the surface of the semiconductor material layer and in the cell trench and the source lead-out region trench by etching, respectively, a difference between the top of the remaining source polycrystalline silicon in a cell trench and the bottom of a top surface of the second oxide layer in the same cell trench is between 5,000 A and 15,000 A, and a height difference between the top of the remaining source polycrystalline silicon in a source lead-out region trench and the bottom of a top surface of the second oxide layer in the same source lead-out region trench is between 3,000 A and 12,000 A.

16. The method for preparing a shielded gate semiconductor device according to claim 11, wherein after removing, by etching, the semiconductor material layer between the trenches and a portion of the source polycrystalline silicon in the cell trench and the source lead-out region trench, a height difference between the top of the remaining source polycrystalline silicon and the bottom of a top surface of the second oxide layer in the cell trench is between 500 A and 1,500 A, and a height difference between the top of the remaining source polycrystalline silicon and the bottom of a top surface of the second oxide layer in the source lead-out region trench is between 0 A and 1,000 A.

17. The method for preparing a shielded gate semiconductor device according to claim 11, wherein thickness of the semiconductor material layer between the trenches that is removed by etching is between 3,000 A and 10,000 A.

18. The method for preparing a shielded gate semiconductor device structure according to claim 11, wherein a third oxide layer with a thickness of 200 A to 1,000 A is grown at a temperature of 950° C. to 1,100° C., and a fourth oxide layer with a thickness of 200 A to 1,200 A is grown at a temperature of 950° C. to 1,100° C.

19. A shielded gate semiconductor device structure prepared and obtained by using the preparing method according to claim 11, wherein the structure comprises:
a cell trench, wherein an inner surface of a lower part of the cell trench is sequentially provided with a second oxide layer and a first oxide layer from outside to inside and an inner surface of an upper part of the cell trench is provided with a fourth oxide layer, wherein source polycrystalline silicon is provided in a space enclosed by the second oxide layer and gate polycrystalline silicon is provided in a space enclosed by the fourth oxide layer, a top surface of the source polycrystalline silicon being provided with a fourth oxide layer, and the gate polycrystalline silicon covering the top surface of the source polycrystalline silicon; and
a source lead-out region trench, wherein an inner surface of the source lead-out region trench is provided with a first oxide layer and a second oxide layer, and source polycrystalline silicon is provided in a space enclosed by the second oxide layer, wherein a top surface of the source polycrystalline silicon is provided with a fourth oxide layer;
wherein in the cell trench and the source lead-out region trench, the top of the second oxide layer is lower than the top of the first oxide layer.

20. The shielded gate semiconductor device structure according to claim 19, wherein total thickness of the first oxide layer and the second oxide layer is between 1,000 A and 8,000 A.
